(19) United States
(12) Patent Application Publication
(10) Pub. No.: US 2015/0056373 A1
(43) Pub. Date: Feb. 26, 2015

(54) DEPOSITION METHOD AND DEPOSITION APPARATUS

(71) Applicants: Natsuki Fukuda, Shizuoka (JP); Kazunori Fukuju, Shizuoka (JP); Yutaka Nishioka, Shizuoka (JP); Koukou Suu, Shizuoka (JP)

(72) Inventors: Natsuki Fukuda, Shizuoka (JP); Kazunori Fukuju, Shizuoka (JP); Yutaka Nishioka, Shizuoka (JP); Koukou Suu, Shizuoka (JP)

(73) Assignee: ULVAC, INC., Kanagawa (JP)

(21) Appl. No.: 14/348,006

(22) PCT Filed: Jul. 25, 2013
(86) PCT No.: PCT/JP2013/004524

§ 371 Date: Mar. 27, 2014

(30) Foreign Application Priority Data
Aug. 9, 2012 (JP) 2012-176936

(51) Int. Cl. C23C 14/00; C23C 16/44; H01J 37/34; C23C 16/455

(52) U.S. Cl. CPC C23C 14/0063; C23C 16/455; C23C 16/4412; H01J 37/3411; H01J 2237/006
USPC 427/255.28; 118/715; 204/192.15; 204/298.07

(57) ABSTRACT

[Object] To provide a deposition method and a deposition apparatus capable of forming a metal compound layer having desired film characteristics uniformly in a substrate surface.

[Solving Means] A deposition method according to an embodiment of the present invention includes evacuating an inside of a vacuum chamber 10 having a deposition chamber 101 formed inside a cylindrical partition wall 20 and an exhaust chamber 102 formed outside the partition wall 20, via an exhaust line 50 connected to the exhaust chamber 102. A process gas containing a reactive gas is introduced into the exhaust chamber 102. With the deposition chamber 101 being maintained at a lower pressure than the exhaust chamber 102, the process gas is supplied to the deposition chamber 101 via a gas flow passage 80 between the partition wall 20 and the vacuum chamber 10.

### TECHNICAL FIELD

The present invention relates to deposition methods and deposition apparatuses which can improve deposition uniformity.

### BACKGROUND ART

Semiconductor memories include volatile memories such as DRAM (Dynamic Random Access Memory) and non-volatile memories such as flash memories. While known non-volatile memories include NAND flash memories and the like, ReRAM (Resistance Random Access Memory) is drawing attention as a device which is capable of being more miniaturized.

ReRAM uses a variable resistor, which changes resistance upon receiving pulse voltages, as a resistance element. A typical type of this variable resistor is at least two layers of metal oxide layers which are different in the degree of oxidation, that is, the resistivity, and has a structure in which these layers are sandwiched between top and bottom electrodes. As a method for forming a laminated structure of oxides having different degrees of oxidation, there is known a method of forming a metal oxide by a so-called reactive sputtering in which a target made of metal is sputtered in an oxygen atmosphere. For example, in the following Patent Document 1, there is described a method of laminating the metal oxide layer on the substrate by the so-called reactive sputtering in which the target made of metal is sputtered in the oxygen atmosphere.

Patent Document 1: Japanese Patent Application Laid-open No. 2008-244018

### DISCLOSURE OF THE INVENTION

### Problem to be Solved by the Invention

However, it is generally difficult to form the metal oxide layer with a desired resistivity uniformly on the substrate because a change in resistivity of the metal oxide layer with respect to a change in oxygen flow rate becomes relatively large. For example, a resistivity distribution is likely to occur in a wafer surface and between wafers, due to the cause such as adsorption of the introduced oxygen on a surface of a target or a surface of a shield (deposition preventive plate). Because of this, the metal oxide layer with a desired resistivity was not able to be formed uniformly in a substrate surface.

In view of the circumstances as described above, an object of the present invention is to provide a deposition method and a deposition apparatus capable of forming a metal compound layer having desired film characteristics uniformly in a substrate surface.

### Means for Solving the Problem

In order to solve the problems described above, a deposition method according to an embodiment of the present invention includes evacuating an inside of a vacuum chamber having a deposition chamber formed inside a cylindrical partition wall and an exhaust chamber formed outside the partition wall, via an exhaust line connected to the exhaust chamber.

A process gas containing a reactive gas is introduced into the exhaust chamber. In a state where the deposition chamber is maintained at a lower pressure than the exhaust chamber, the process gas is supplied to the deposition chamber via a gas flow passage formed between the partition wall and the vacuum chamber.

A deposition apparatus according to an embodiment of the present invention includes a vacuum chamber, a cylindrical partition wall, an exhaust line, a gas introduction line and a gas flow passage.

The vacuum chamber has a bottom wall portion and a top plate portion.

The partition wall is disposed inside the vacuum chamber, and divides the inside of the vacuum chamber into a deposition chamber and an exhaust chamber.

The exhaust line is connected to the exhaust chamber, and is configured to commonly evacuate an inside of the deposition chamber and the exhaust chamber.

The gas introduction line is connected to the exhaust chamber, and is configured to introduce a process gas containing a reactive gas into the exhaust chamber.

The gas flow passage is provided between the bottom wall portion and the partition wall, and supplies the process gas introduced in the exhaust chamber to the deposition chamber.

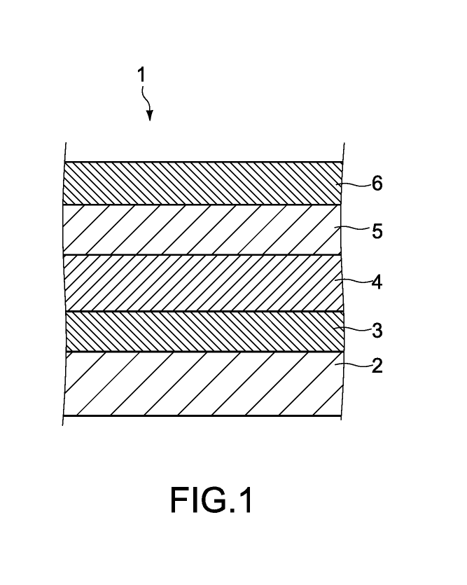

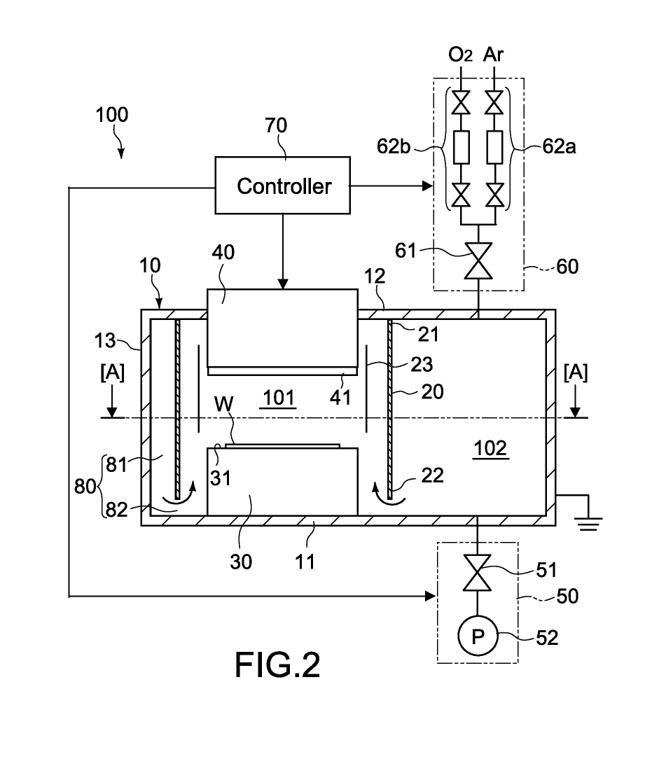

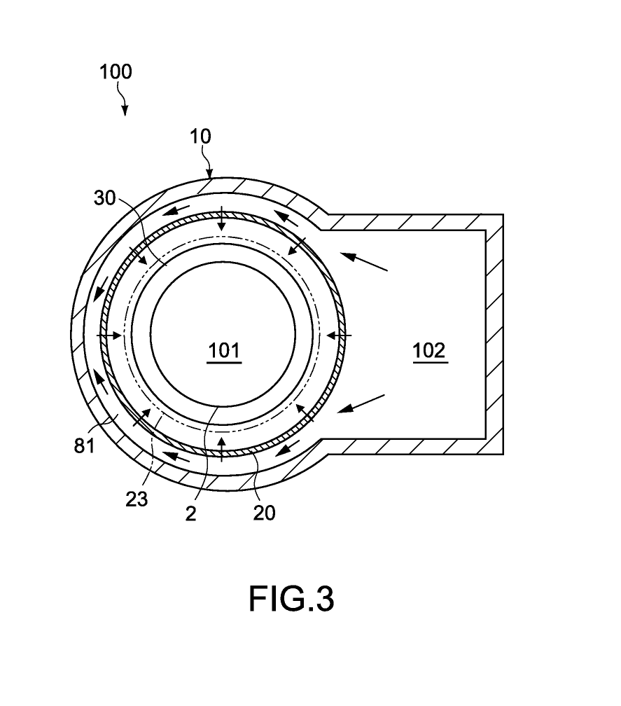

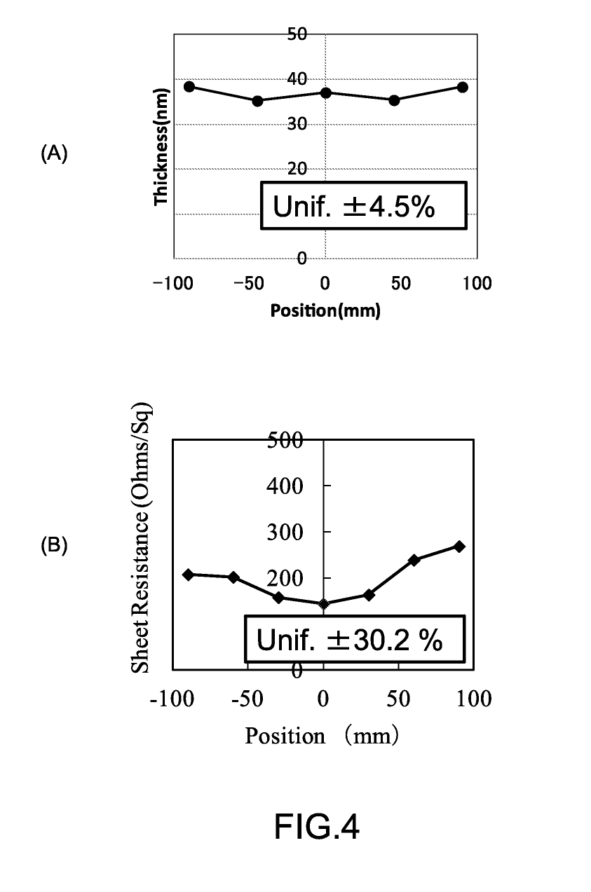

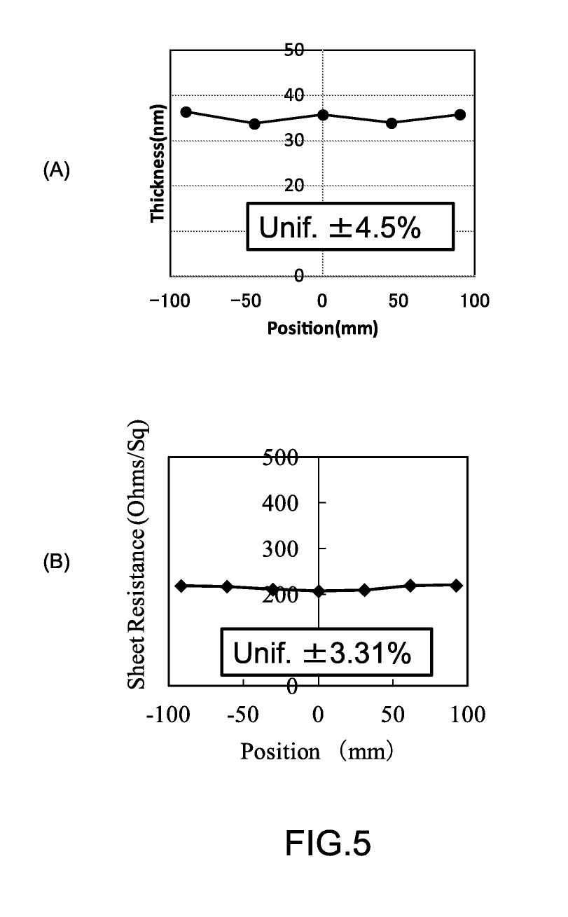

### BRIEF DESCRIPTION OF DRAWINGS

[FIG. 1] A schematic sectional view showing a configuration example of a resistance change element.

[FIG. 2] A schematic side cross-sectional view of a deposition apparatus according to an embodiment of the present invention.

[FIG. 3] A cross-sectional view taken along the line [A]-[A] of FIG. 2.

[FIG. 4] A result of an experiment showing a film thickness [nm] and a sheet resistance [Ω/□] in a substrate surface of a tantalum oxide layer formed by a deposition apparatus of a comparative example.

[FIG. 5] A result of an experiment showing a film thickness [nm] and a sheet resistance [Ω/□] in a substrate surface of a tantalum oxide layer formed by a deposition apparatus of the embodiment.

### MODE(S) FOR CARRYING OUT THE INVENTION

A deposition method according to an embodiment of the present invention includes evacuating an inside of a vacuum chamber having a deposition chamber formed inside a cylindrical partition wall and an exhaust chamber formed outside the partition wall, via an exhaust line connected to the exhaust chamber.

A process gas containing a reactive gas is introduced into the exhaust chamber. In a state where the deposition chamber is maintained at a lower pressure than the exhaust chamber, the process gas is supplied to the deposition chamber via a gas flow passage formed between the partition wall and the vacuum chamber.

In the above-described deposition method, the process gas is supplied from the exhaust chamber to the deposition chamber via the gas flow passage, using a pressure difference between the deposition chamber and the exhaust chamber. At this time, since the partition wall is formed in a cylindrical shape, the process gas is supplied in an isotropic manner from the exhaust chamber to the deposition chamber. This allows reducing variations in concentration distribution of the reactive gas on the substrate; thereby forming a metal compound layer having desired film characteristics uniformly in a substrate surface.

Examples of the reactive gases which may be employed include gases containing oxygen, nitrogen, or carbon. The reactive gas may be appropriately selected, depending on the kinds and the film characteristics of the target metal compound layer. For example, for forming a metal oxide layer, oxygen may be employed as the reactive gas, and according to the added amount of oxygen, a resistivity of the metal oxide layer may be controlled. Examples of the process gases which may be employed include mixed gases of any of the above-mentioned reactive gases and a rare gas such as argon.

The supplying the process gas to the deposition chamber may be supplying the process gas to the deposition chamber via an annular passage portion and a flow-passage portion. The annular passage portion is formed between the vacuum chamber and the partition wall. The flow-passage portion is formed between the partition wall and a bottom wall portion of the vacuum chamber.

With this configuration, for example, in cases where a metal target is to be placed at a top plate portion of the vacuum chamber, it becomes possible to supply the process gas to the deposition chamber from a position more distant from the target, and oxidation of the metal target due to contact with the reactive gas, or the like, may thus be reduced. This allows reducing variations in degree of oxidation, or the like, of a surface of the target; thereby improving in-plane uniformity of a physical property (for example, resistivity) of the sputter-deposited metal compound layer.

A deposition apparatus according to an embodiment of the present invention includes a vacuum chamber, a cylindrical partition wall, an exhaust line, a gas introduction line and a gas flow passage.

The vacuum chamber has a bottom wall portion and a top plate portion.

The partition wall is disposed inside the vacuum chamber, and divides the inside of the vacuum chamber into a deposition chamber and an exhaust chamber.

The exhaust line is connected to the exhaust chamber, and is configured to commonly evacuate an inside of the deposition chamber and the exhaust chamber.

The gas introduction line is connected to the exhaust chamber, and is configured to introduce a process gas containing a reactive gas into the exhaust chamber.

The gas flow passage is provided between the bottom wall portion and the partition wall, and supplies the process gas introduced in the exhaust chamber to the deposition chamber.

The above-described deposition apparatus is capable of generating a predetermined pressure difference between the deposition chamber and the exhaust chamber during deposition. This allows the process gas to be supplied to the deposition chamber in an isotropic manner; thereby forming a metal compound layer having desired film characteristics uniformly in a substrate surface.

The deposition chamber may include a stage and a sputtering target. The stage is placed at the bottom wall portion. The stage has a support surface for supporting a substrate. The target is placed at the top plate portion to confront the stage. In this case, the gas flow passage is located closer to the bottom wall portion than the support surface.

This allows the process gas to be supplied to the deposition chamber from a position more distant from the target. It is thus possible to reduce variations in degree of oxidation, or the like, of a surface of the target; thereby improving in-plane uniformity of the sputter-deposited metal compound layer.

The gas flow passage may include an annular passage portion and at least one flow-passage portion. The annular passage portion is formed between the vacuum chamber and the partition wall. The flow-passage portion is in communication with the passage portion and is formed around the partition wall.

This allows the process gas to be supplied to the deposition chamber in an isotropic manner; and it is thus possible to stably form a metal compound layer having good in-plane uniformity.

Hereinafter, with reference to the drawings, an embodiment of the present invention will be described. In this embodiment, a deposition apparatus to be used for forming metal oxide layers which make up a resistance change element and its deposition method will be described as an example.

### Resistance Change Element

First, an outline of a configuration of a resistance change element will be described. FIG. 1 is a schematic sectional view showing a configuration example of the resistance change element.

A resistance change element 1 has a substrate 2, a bottom electrode layer 3, a first metal oxide layer 4, a second metal oxide layer 5 and a top electrode layer 6.

The substrate 2 may be made up of a silicon substrate but is not limited thereto. Other substrate materials such as a glass substrate may also be used.

The bottom electrode layer 3 is formed on the substrate 2, and is made of Ta in this embodiment. However, the material is not limited thereto. For example, transition metals such as Hf, Zr, Ti, Al, Fe, Co, Mn, Sn, Zn, Cr, V and W; or the alloys thereof (silicon alloys such as TaSi, WSi and TiSi; nitrogen compounds such as TaN, WaN, TiN and TiAlN; carbon alloys such as TaC; or the like) may be used.

The first metal oxide layer 4 is formed on the bottom electrode layer 3, and is made of TaOₓ in this embodiment. Here, the TaOₓ used for the first metal oxide layer 4 is an oxide having near-stoichiometric composition. However, the material is not limited thereto. For example, ZrOₓ, HfOₓ, TiOₓ, AlOₓ, SiOₓ, FeOₓ, NiOₓ, CoOₓ, MnOₓ, SnOₓ, ZnOₓ, VOₓ, WOₓ, CuOₓ or other two dimensional oxides of transition metals or the like may be used. A resistivity of the first metal oxide layer 4 is not limited as long as desired characteristics of the element can be obtained; but may be, for example, greater than 10⁶Ω cm.

The second metal oxide layer 5 is formed on the first metal oxide layer 4, and is made of TaOₓ in this embodiment. Here, the TaOₓ used for the second metal oxide layer 5 has a lower degree of oxidation than the TaOₓ forming the first metal oxide layer 4, and is an oxide containing a large number of oxygen vacancies. However, the material is not limited thereto. For example, ZrOₓ, HfOₓ, TiOₓ, AlOₓ, SiOₓ, FeOₓ, NiOₓ, CoOₓ, MnOₓ, SnOₓ, ZnOₓ, VOₓ, WOₓ, CuOₓ or other two dimensional oxides of transition metals or the like may be used.

The second metal oxide layer 5 may be made up of an oxide of the same metal as that of the first metal oxide layer 4; or may be made up of an oxide of a metal different from that of the first metal oxide layer 4. A resistivity of the second metal oxide layer 5 may be any resistivity lower than that of the first metal oxide layer 4; and may be, for example, greater than 1Ω cm and lower than 10⁶Ω cm.

The top electrode layer 6 is formed on the second metal oxide layer 5, and is made of Ta in this embodiment. However, the material is not limited thereto. For example, transition metals such as Hf, Zr, Ti, Al, Fe, Co, Mn, Sn, Zn, Cr, V and W; or the alloys thereof (silicon alloys such as TaSi, WSi and TiSi; nitrogen compounds such as TaN, WaN, TiN and TiAlN; or carbon alloys such as TaC) may be used.

In the resistance change element 1 of this embodiment, since the first metal oxide layer 4 has a higher degree of oxidation than that of the second metal oxide layer 5, it has a higher resistivity than the second metal oxide layer. In this case, when a positive voltage and a negative voltage are respectively applied to the top electrode layer 6 and the bottom electrode layer 3, the oxygen ions (O₂⁻) in the first metal oxide layer 4 which has a high resistivity would diffuse into the second metal oxide layer 5 which has a low resistivity. The resistance of the first metal oxide layer 4 would be lowered (low-resistance state). Conversely, when the positive voltage and the negative voltage are respectively applied to the bottom electrode layer 3 and the top electrode layer 6, the O₂⁻ would diffuse from the second metal oxide layer 5 into the first metal oxide layer 4. The degree of oxidation of the first metal oxide layer 4 would increase again, and the resistance thereof becomes high (high-resistance state).

Thus, the first metal oxide layer 4 switches reversibly between its low-resistance state and high-resistance state by a voltage control between the bottom electrode layer 3 and the top electrode layer 6. Moreover, the low-resistance state and the high-resistance state can be kept without the voltage applied. The resistance change element 1 is thus able to be used as a non-volatile memory device.

### Deposition Apparatus

FIGS. 2 and 3 are schematic structural views showing a deposition apparatus according to an embodiment of the present invention. FIG. 2 is a schematic side cross-sectional view; and FIG. 3 is a cross-sectional view taken along the line [A]-[A] of FIG. 2. A deposition apparatus 100 of this embodiment may be configured to serve as a sputtering apparatus for forming the first and second metal oxide layers 4 and 5 in a process of producing the resistance change element 1.

The deposition apparatus 100 has a vacuum chamber 10. The vacuum chamber 10 may be formed of a metal material such as aluminum and stainless steel, and is connected to the ground potential. The vacuum chamber 10 has a bottom wall portion 11, a top plate portion 12 and a side wall portion 13. The vacuum chamber 10 is thus configured to maintain its inside in a predetermined vacuum atmosphere.

Inside the vacuum chamber 10, a stage 30 and a target unit 40 are disposed. The stage 30 has a support surface 31 for supporting a substrate W. The target unit 40 includes a metal target 41 (Ta target, in this embodiment). The stage 30 is provided at the bottom wall portion 11 of the vacuum chamber 10, and the target unit 40 is provided at the top plate portion 12 of the vacuum chamber 10. The stage 30 and the target unit 40 are disposed to confront each other.

The stage 30 may be provided with a chucking mechanism for electrostatically or mechanically holding the substrate W to the support surface 31, a temperature control unit for heating or cooling the substrate W to a predetermined temperature, and the like.

The target unit 40 may include a backing plate for supporting the target 41, a magnetic circuit for forming a magnetic field on a surface of the target 41, and the like. The target unit 40 may be connected to a power source for supplying a predetermined electric power (direct current, alternating current or high frequency power) to the backing plate. The power source may be configured as a part of the target unit 40, or may be configured separately from the target unit 40.

The deposition apparatus 100 has a cylindrical partition wall 20 which divides the inside of the vacuum chamber into a deposition chamber 101 and an exhaust chamber 102. The partition wall 20 of this embodiment is made up of a metal plate having a first end portion 21 affixed to the top plate portion 12 and a second end portion 22 facing the bottom wall portion 11, which metal plate is made of, for example, aluminum or stainless steel.

The partition wall 20 has a cylindrical shape in a size capable of accommodating the stage 30 and the target unit 40 inside. The partition wall 20 forms the deposition chamber 101 in its inside. Further, in the deposition chamber 101, there is placed a cylindrical deposition preventive plate 23 so as to surround an area between the stage 30 and the target unit 40.

Outside the partition wall 20, the exhaust chamber 102 is formed. The exhaust chamber 102 can be evacuated by an exhaust line 50 connected to the vacuum chamber 10 until the exhaust chamber 102 reaches a predetermined vacuum pressure. The exhaust line 50 includes an exhaust valve 51 and a vacuum pump 52 connected to the exhaust chamber 102 via the exhaust valve 51. For the vacuum pump 52, for example, a turbo-molecular pump may be used, and an auxiliary pump may be additionally connected thereto, when necessary.

Further, to the exhaust chamber 102, a gas introduction line 60 is connected. In this embodiment, a mixed gas of argon gas for sputtering and oxygen which serves as a reactive gas may be employed.

The gas introduction line 60 includes a main valve 61; an argon introduction line 62a and an oxygen introduction line 62b each connected to the exhaust chamber 102 via the main valve. These introduction lines 62a and 62b may include a plurality of valves, mass flow controllers, gas sources and the like.

The deposition chamber 101 and the exhaust chamber 102 are in communication with each other via a gas flow passage 80. The gas flow passage 80 includes an annular passage portion 81 formed between the side wall portion 13 of the vacuum chamber 10 and an outer peripheral surface of the partition wall 20; and a flow-passage portion 82 formed around the partition wall 20 to be in communication with the passage portion 81.

In this embodiment, the flow-passage portion 82 is configured as a plurality of holes. However, the flow-passage portion 82 may also be configured as an arc-shape slit formed over the entire periphery of the partition wall 20, or the like. In addition, the flow-passage portions 82 may also be configured as an annular gap between the second end portion 22 of the partition wall 20 and the bottom wall portion 11 of the vacuum chamber 10. A size (width or height) of the above-mentioned holes, slit or gap is not particularly limited, but may be set to, for example, about 0.1 mm to 1 mm.

A position where the low-passage portion 82 is formed is not particularly limited. However, by providing the flow-passage portion 82 at a position more distant from the target 41, it becomes possible to reduce surface reaction (oxidation) of the target 41 due to the reactive gas (oxygen) to be supplied to the deposition chamber 101 via the flow-passage portion 82. In this embodiment, the flow-passage portion 82 is located closer to the bottom wall portion 11 of the vacuum chamber 10 than the support surface 31 of the stage 30.

The deposition apparatus 100 further includes a controller 70. The controller 70 is typically made up of a computer and is configured to control operation of the target unit 40, the exhaust line 50, the gas introduction line 60 and the like.

### Deposition Method

Next, a deposition method according to this embodiment will be described along with an exemplary operation of the deposition apparatus 100.

First, the substrate W is placed on the support surface 31 of the stage 30. Here, the substrate 2 (FIG. 1) having the bottom electrode layer 3 formed on a top surface thereof will be used as the substrate W. Next, the controller 70 drives the exhaust line 50 to evacuate the deposition chamber 101 formed inside the partition wall 20 and the exhaust chamber 102 formed outside the partition wall 20, each to a predetermined vacuum pressure. The deposition chamber 101 is evacuated by the exhaust line 50 via the gas flow passage 80 and the exhaust chamber 102.

After the deposition chamber 101 and the exhaust chamber 102 reaches the predetermined vacuum pressure, the controller 70 drives the gas introduction line 60 to introduce the process gas into the exhaust chamber 102. During this step, the exhaust chamber 102 is continuously evacuated via the exhaust line 50. That is, the controller 70 introduces a predetermined flow rate of the process gas into the exhaust chamber 102 while evacuating the exhaust chamber 102 at a predetermined evacuation rate.

In this embodiment, a mixed gas of argon and oxygen is employed as the process gas. The mixing ratio of argon and oxygen is not particularly limited, and the amount of oxygen to be added may be controlled according to the resistivity of the metal oxide layer to be formed. As described above, the deposition apparatus 100 is used for forming the first and second metal oxide layers 4 and 5 of the resistance change element 1 shown in FIG. 1. At the time of forming the first metal oxide layer 4, the oxygen flow rate is set to a flow rate at which a tantalum oxide having stoichiometric composition can be formed (first flow rate); and at the time of forming the second metal oxide layer 5, the oxygen flow rate is set to a flow rate at which a predetermined tantalum oxide in which oxygen content is deficient can be formed (second flow rate). The first and second flow rates are set by the oxygen introduction line 62b; and setting of the flow rates by the oxygen introduction line 62b is controlled by the controller 70.

The process gas introduced in the exhaust chamber 102 is supplied to the deposition chamber 101 via the gas flow passage 80. As a result of introduction of the process gas into the exhaust chamber 102, the pressure of the deposition chamber 101 becomes lower than the exhaust chamber 102. Maintaining this state, the process gas introduced in the exhaust chamber 102 is allowed to diffuse toward the deposition chamber 101 in an isotropic manner, via the gas flow passage 80 being formed between the vacuum chamber 10 and the partition wall 20 (passage portion 81 and flow-passage portion 82).

Meanwhile, the controller 70 controls the target unit 40 to allow plasma of the process gas to be formed in the deposition chamber 101. Argon ions in the plasma sputters the target 41; sputtered particles emitted from the target 41 reacts with the oxygen; and the resulting generated tantalum oxide particles would be deposited on the surface of the substrate W. Thus, a tantalum oxide (TaOₓ) layer would be formed on the substrate W.

The controller 70 switches the film to be formed, from the first metal oxide layer 4 to the second metal oxide layer 5, by controlling the oxygen flow rate for the oxygen introduction line 62b. In this embodiment, the first metal oxide layer 4 is formed by setting of the oxygen flow rate to the first flow rate, and the second metal oxide layer 5 is formed by setting of the oxygen flow rate to the second flow rate. This allows successive deposition of the first metal oxide layer 4 and the second metal oxide layer 5 having different resistivity from each other, in the same vacuum chamber 10. This makes it possible to improve productivity.

As described above, in this embodiment, the process gas is supplied from the exhaust chamber 102 to the deposition chamber 101 via the gas flow passage 80, using a pressure difference between the deposition chamber 101 and the exhaust chamber 102. At this time, since the partition wall 20 is formed in a cylindrical shape, the process gas is supplied in an isotropic manner from the exhaust chamber 102 to the deposition chamber 101. This allows reducing variations in concentration distribution of the reactive gas on the substrate W; thereby forming a metal compound layer having desired film characteristics uniformly in a surface of the substrate W.

In addition, in this embodiment, it is configured so that the process gas is supplied to the deposition chamber 101 via the flow-passage portion 82 formed between the partition wall 20 and the bottom wall portion 11 of the vacuum chamber 10. This allows the process gas to be supplied to the deposition chamber 101 from a position more distant from the target 41 placed at the top plate portion 12 of the vacuum chamber 10, and oxidation of the target 41 due to contact with the oxygen in the process gas may thus be reduced. This allows reducing variations in degree of oxidation of the surface of the target 41; thereby improving in-plane uniformity of resistivity of the sputter-deposited metal oxide layer.

Figures (A) and (B) in FIG. 4 respectively show a film thickness [nm] and a sheet resistance [Ω/□] in a substrate surface of a tantalum oxide layer formed by a deposition apparatus (sputtering apparatus) which does not have the partition wall 20. In the measurement of the sheet resistance, four-terminal method was employed. In this experiment example, the in-plane uniformity of the film thickness was ±4.5%. The in-plane uniformity of the sheet resistance was ±30.2%.

In particular, as shown in (B) of FIG. 4, there was a tendency that the sheet resistance in the peripheral part of the substrate was higher than the sheet resistance in the center part of the substrate. It can be considered that this was due to easiness of oxidation of the peripheral part of the target compared to the center part of the target, which oxidation would be made by the oxygen in the process gas supplied to the deposition chamber. In addition, some variations were also observed in the sheet resistance in the peripheral part of the substrate, and it can be considered that this was because the process gas was not supplied in an isotropic manner to the deposition chamber.

On the other hand, (A) and (B) in FIG. 5 respectively show a film thickness [nm] and a sheet resistance [Ω/□] in a substrate surface of a tantalum oxide layer formed by the deposition apparatus 100 of the embodiment. In the measurement of the sheet resistance, four-terminal method was employed. In this experiment example, the in-plane uniformity of the film thickness was ±4.5%. The in-plane uniformity of the sheet resistance was ±3.31%.

According to this embodiment, as shown in (B) of FIG. 5, it was confirmed that both of the film thickness and the sheet resistance result in higher uniformity in the substrate surface. It can be considered that this was due to the isotropic supply of the process gas to the deposition chamber 101. Further, it can be considered that this was because the target 41 was prevented from being oxidized locally, since the flow-passage portion 82 for supplying the process gas from the exhaust chamber 102 to the deposition chamber 101 was located on the side opposite to the target 41 (at the bottom wall portion 11 of the vacuum chamber).

A differential pressure between the deposition chamber 101 and the exhaust chamber 102 is not particularly limited, but may be set appropriately depending on the volume of each chamber, pressure during the deposition, or the like. In the experiment example of (A) and (B) of FIG. 5, the volume of the deposition chamber 101 was about 0.027 m³ and the volume of the exhaust chamber 102 was about 0.021 m³. The pressure during the deposition was 1.0 Pa in the deposition chamber 101 and 1.5 Pa in the exhaust chamber 102. The process gas was with flow rates of 100 sccm of argon and 20 sscm of oxygen.

As described above, according to this embodiment, as it is possible to form a metal oxide layer with high in-plane uniformity of resistivity on a substrate, it is possible to stably produce the resistance change element 1 having the first and second metal oxide layers 4 and 5 with their resistivity highly controlled. This allows the resistivity variations among the elements and the size of the element to be reduced, and thus, for example, an increase of the voltage required for the element's initial operation called “forming” may be suppressed. In addition, since the increase of the forming voltage can be suppressed, it may prevent breakage of the element; and suppress increase of switching operation voltage and power consumption. Furthermore, it makes it possible to prevent unstable formation of conductive paths called “filament” and thus to prevent variations in the resistivity during readout.

Hereinabove, the embodiment of the present invention has been described, but the present invention is not limited thereto, and can be variously modified within the scope without departing from the gist of the present invention, as a matter of course.

For example, in the above-described embodiment, oxygen has been employed as the reactive gas to be added to the process gas; but the kinds of the reactive gases may be appropriately selected, depending on the kinds and the film characteristics of the target metal compound layer. For example, for forming a metal nitride layer, a gas containing nitrogen (for example, ammonia) may be selected; and for forming a metal carbide layer, a gas containing carbon (for example, methane) may be selected.

Further, in the above-described embodiment, the shape of the partition wall 20 forming the deposition chamber 101 has been formed in a cylindrical shape. However, the shape is not limited thereto, and can be appropriately changed according to the shape of the vacuum chamber, to polygonal cylindrical shape, truncated cone shape, or the like.

Still further, in the above-described embodiment, the exhaust chamber 102 has been provided with one exhaust line 50 and one gas introduction line 60, but it is not limited thereto. A plurality of positions of the exhaust chamber 102 may also be provided with exhaust lines 50 and gas introduction lines 60.

Still further, in the above-described embodiment, a sputtering apparatus has been described as an example of the deposition apparatus, but it is not limited thereto. The present invention is also applicable to a CVD apparatus, a vacuum deposition apparatus, and other various deposition apparatuses and deposition methods for forming films in a vacuum with the use of a process gas containing a reactive gas.

### DESCRIPTION OF REFERENCE NUMERALS

1 resistance change element
4, 5 metal oxide layers
10 vacuum chamber
20 partition wall
30 stage
40 target unit
50 exhaust line
60 gas introduction line
70 controller
80 gas flow passage
81 passage portion
82 flow-passage portion
100 deposition apparatus
101 deposition chamber
102 exhaust chamber

1. A deposition method comprising:
evacuating an inside of a vacuum chamber having a deposition chamber formed inside a cylindrical partition wall and an exhaust chamber formed outside the partition wall, via an exhaust line connected to the exhaust chamber; and
introducing a process gas containing a reactive gas into the exhaust chamber and, in a state where the deposition chamber is maintained at a lower pressure than the exhaust chamber, supplying the process gas to the deposition chamber via a gas flow passage formed between the partition wall and the vacuum chamber.

2. The deposition method according to claim 1, further comprising forming a metal compound layer on a substrate by sputtering a metal target in the deposition chamber.

3. The deposition method according to claim 1, wherein
the supplying the process gas to the deposition chamber is supplying the process gas to the deposition chamber via an annular passage portion formed between the vacuum chamber and the partition wall, and
a flow-passage portion formed between the partition wall and a bottom wall portion of the vacuum chamber.

4. The film forming method according to claim 1, wherein the process gas includes a mixed gas of argon and oxygen, for forming a metal oxide layer on the substrate.

5. A deposition apparatus comprising:
a vacuum chamber having a bottom wall portion and a top plate portion;
a cylindrical partition wall disposed inside the vacuum chamber, the partition wall dividing the inside of the vacuum chamber into a deposition chamber and an exhaust chamber;
an exhaust line connected to the exhaust chamber, the exhaust line being configured to commonly evacuate an inside of the deposition chamber and the exhaust chamber;
a gas introduction line connected to the exhaust chamber, the gas introduction line being configured to introduce a process gas containing a reactive gas into the exhaust chamber; and
a gas flow passage provided between the bottom wall portion and the partition wall, to supply the process gas introduced in the exhaust chamber to the deposition chamber.

6. The deposition apparatus according to claim 5, wherein the deposition chamber includes:
a stage placed at the bottom wall portion, the stage having a support surface for supporting a substrate, and
a sputtering target placed at the top plate portion to confront the stage, and wherein the gas flow passage is located closer to the bottom wall portion than the support surface.

7. The deposition apparatus according to claim 5, wherein the gas flow passage includes an annular passage portion formed between the vacuum chamber and the partition wall; and
a flow-passage portion in communication with the passage portion, the flow-passage portion being formed around the partition wall.
